(19) United States
(12) Patent Application Publication
(10) Pub. No.: US 2012/0137036 A1
(43) Pub. Date: May 31, 2012

(54) BASIC INPUT OUTPUT SYSTEM REFRESH APPARATUS

(75) Inventors: YUN-SHAN XIAO, Shenzhen City (CN); JIAN-CHUN PAN, Shenzhen City (CN); HAI-QING ZHOU, Shenzhen (CN)

(73) Assignees: HON HAI PRECISION INDUSTRY CO., LTD., Tu-Cheng (TW); HONG FU JIN PRECISION INDUSTRY (ShenZhen), CO, LTD., Shenzhen City (CN)

(21) Appl. No.: 12/970,956

(22) Filed: Dec. 17, 2010

(30) Foreign Application Priority Data
Nov. 25, 2010 (CN) 201010559128.3

(51) Int. Cl. H05K 7/10

(52) U.S. Cl. 710/301

(57) ABSTRACT

A basic input output system (BIOS) refresh apparatus includes a jumper device, which includes a first pin, a second pin connected to a power source through a resistor, a third pin, and a grounded fourth pin. A master BIOS socket includes a voltage pin connected to the power source and a signal pin connected to the first pin of the jumper device. A slave BIOS socket includes a voltage pin connected to the power source and a signal pin connected to the third pin of the jumper device. Other pins of the master BIOS socket are correspondingly connected to other pins of the slave BIOS socket. The signal pin of the master BIOS socket or the slave BIOS socket receives high level signal to make a corresponding BIOS chip mounted thereon work when the first or third pin is connected to the second pin of the jumper device.

### BACKGROUND

1. Field of the Invention

The present disclosure relates to a basic input output system (BIOS) refresh apparatus.

2. Description of Related Art

At present, a traditional way to solve problems of a motherboard caused by BIOS failure is replacing the BIOS, which requires specialized tools and professional skill. While another way is having two separate BIOSes on the motherboard, which requires additional real estate on the motherboard, thus, reducing the efficiency and the number of components on the motherboard.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a circuit diagram of a basic input output system (BIOS) refresh apparatus in accordance with an exemplary embodiment of the present disclosure.

FIG. 2 and FIG. 3 are schematic diagrams of the BIOS refresh apparatus of FIG. 1.

### DETAILED DESCRIPTION

The disclosure, including the drawings, is illustrated by way of example and not by limitation. It should be noted that references to “an” or “one” embodiment in this disclosure are not necessarily to the same embodiment, and such references mean at least one.

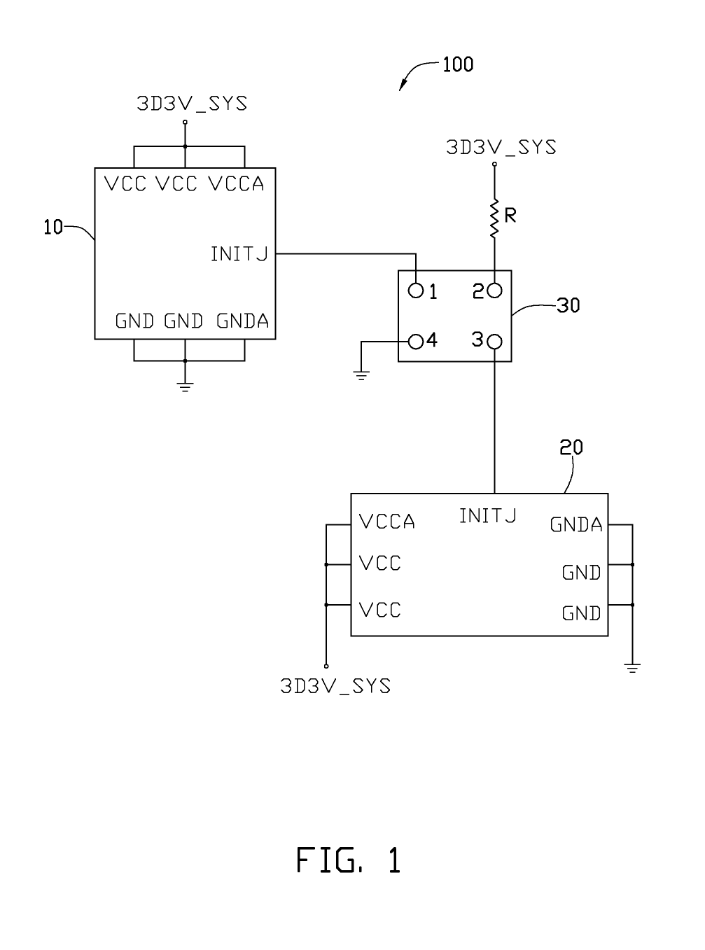

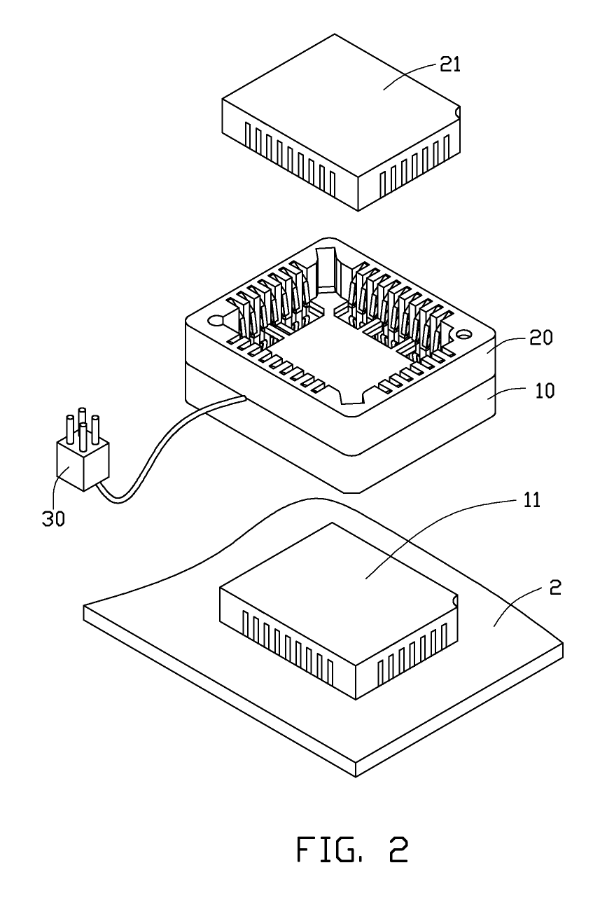

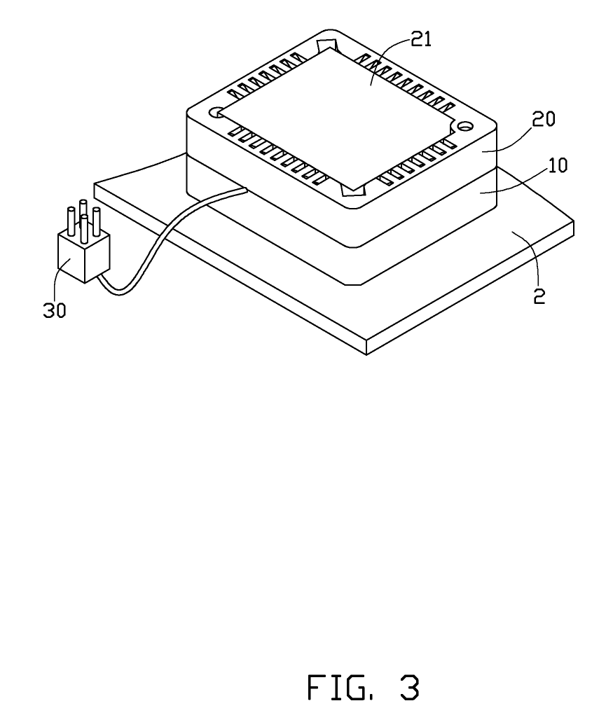

Referring to FIG. 1 to FIG. 3, a basic input output system (BIOS) refresh apparatus 100 is configured to refresh a BIOS chip 11 of a motherboard 2 or copy a BIOS file from the BIOS chip 11, which is good to the BIOS chip 21, which is blank. The BIOS refresh apparatus 100 in accordance with an exemplary embodiment includes a master BIOS socket 10, a slave BIOS socket 20, a jumper device 30, and a resistor R. The master BIOS socket 10 is substantially similar to the slave BIOS socket 20. Voltage pins VCC and VCCA of the master BIOS socket 10 and the slave BIOS socket 20 are connected to a power source 3D3V_SYS of a motherboard through a first cable. Ground pins GND and GNDA of the master BIOS socket 10 and the slave BIOS socket 20 are grounded through a second cable. A signal pin INITJ of the master BIOS socket 10 is connected to a first pin 1 of the jumper device 30. A signal pin INITJ of the slave BIOS socket 20 is connected to a third pin 3 of the jumper device 30. A second pin 2 of the jumper device 30 is connected to the power source 3D3V_SYS through the resistor R. A fourth pin 4 of the jumper device 30 is grounded. Other pins of the master BIOS socket 10 are correspondingly connected to other pins of the slave BIOS socket 20. In one embodiment, the power source 3D3V_SYS is a 3.3 volt (V) power source.

In use, when the BIOS refresh apparatus 100 is used to refresh the BIOS chip 11 of the motherboard 2, a good BIOS chip 21 is mounted to the slave BIOS socket 20, and the master BIOS socket 10 covers on and electrically connects to the BIOS chip 11 of the motherboard 2. The first pin 1 and the fourth pin 4 of the jumper device 30 are connected together through a first jumper (not shown), and the second pin 2 and the third pin 3 of the jumper device 30 are connected together through a second jumper (not shown). The motherboard 2 is powered on, the BIOS chip 21 mounted on the slave BIOS socket 20 receives a high level signal from the signal pin INITJ of the slave BIOS socket 20 to guide the motherboard into a disk operating system (DOS) mode or a Windows mode. After that, the first pin 1 and the second pin 2 of the jumper device 30 are connected together through the first jumper, and the third pin 3 and the fourth pin 4 of the jumper device 30 are connected together through the second jumper. Thus, the signal pin INITJ of the master BIOS socket 20 receives a low level signal, and at the same time, the motherboard is in the DOS mode or the Windows mode, therefore, a BIOS program stored in the motherboard can automatically refresh the BIOS chip 11 of the motherboard 2. The BIOS refresh apparatus 100 can be removed after the BIOS chip 11 is refreshed. The motherboard 2 is powered on again, the BIOS chip 11 of the motherboard 2 guides the motherboard 2 into the DOS mode or the Windows mode, namely, the BIOS chip 11 of the motherboard 2 is restored.

When the BIOS refresh apparatus 100 is used to copy the BIOS file from the BIOS chip 11 of the motherboard 2 to a blank BIOS chip 21, the blank BIOS chip 21 is mounted to the slave BIOS socket 20, and the master BIOS socket 10 covers on and electrically connects to the BIOS chip 11 of the motherboard 2. The first pin 1 and the second pin 2 of the jumper device 30 are connected together through a first jumper (not shown), and the third pin 3 and the fourth pin 4 of the jumper device 30 are connected together through a second jumper (not shown). The motherboard 2 is powered on, and the BIOS chip 11 of the motherboard 2 receives a high level signal through the signal pin INITJ of the master BIOS socket 10, to guide the motherboard 2 into a DOS mode or a Windows mode. After that, the first pin 1 and the fourth pin 4 of the jumper device 30 are connected together through the first jumper, and the second pin 2 and the third pin 3 of the jumper device 30 are connected together through the second jumper. The signal pin INITJ of the slave BIOS socket 20 receives a high level signal, and at the same time, the motherboard 2 is in the DOS mode or the Windows mode, therefore, a BIOS program stored in the motherboard 2 can automatically copy the BIOS file from the BIOS chip 11 of the motherboard 2 to the blank BIOS chip 21. The BIOS refresh apparatus 100 can be removed after the BIOS file of the BIOS chip 11 is copied, and then the blank BIOS chip 21 mounted on the slave BIOS socket 20 can be removed.

The BIOS refresh apparatus 100 can automatically refresh the BIOS chip 11 of the motherboard 2 and copy the BIOS file of the BIOS chip 11 of the motherboard 2 to a blank BIOS chip 21. Therefore, the BIOS refresh apparatus 100 is simple and cost effective.

It is to be understood, however, that even though numerous characteristics and advantages of the disclosure have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A basic input output system (BIOS) refresh apparatus comprising:
a resistor;
a jumper device comprising a first pin, a second pin connected to a power source through the resistor, a third pin, and a grounded fourth pin;
a master BIOS socket comprising a voltage pin connected to the power source, a ground pin grounded, and a signal pin connected to the first pin of the jumper device; and
a slave BIOS socket comprising a voltage pin connected to the power source, a ground pin grounded, and a signal pin connected to the third pin of the jumper device, wherein other pins of the master BIOS socket are correspondingly connected to other pins of the slave BIOS socket;
wherein the first and third pins of the jumper device are selectively connected to the second pin or the fourth pin of the jumper device, the signal pin of the master BIOS socket or the slave BIOS socket receives a high level signal to make a corresponding BIOS chip mounted thereon work in response to the first or third pin being connected to the second pin of the jumper device.

2. The BIOS refresh apparatus as claimed in claim 1, wherein the master BIOS socket is configured to cover on a first BIOS chip which needs to be refreshed, and the slave BIOS socket is configured to mount a second BIOS chip, which has a BIOS file and works normally.

3. The BIOS refresh apparatus as claimed in claim 1, wherein the master BIOS socket is configured to cover on a BIOS chip, which has a BIOS file, and the slave BIOS socket is configured to mount a blank BIOS chip.

4. The BIOS refresh apparatus as claimed in claim 1, wherein the power source is a 3.3 volt power source.
